(19) United States
(12) Patent Application Publication
(10) Pub. No.: US 2007/0222032 A1
(43) Pub. Date: Sep. 27, 2007

(54) Bipolar transistor and method for producing a bipolar transistor

(75) Inventors: Herbert Schaefer, Hoehenkirchen-Siegertsbrunn (DE); Josef Boeck, Munich (DE); Rudolf Lachner, Ingolstadt (DE); Thomas Meister, Taufkirchen (DE)

Correspondence Address: Maginot, Moore & Beck;Chase Tower, Suite 3250, 111 Monument Circle, Indianapolis, IN, 46204, US

(73) Assignee: Infineon Technologies AG, Munich (DE)

(21) Appl. No.: 11/716,526

(22) Filed: Mar. 9, 2007

(30) Foreign Application Priority Data
Mar. 10, 2006 (DE) 102006011240.7-33

(51) Int. Cl. H01L 27/082

(52) U.S. Cl. 257/565

(57) ABSTRACT

A bipolar transistor has a base, an emitter and an emitter contact. The emitter has a monocrystalline layer and a polycrystalline layer, which are disposed between the base and the emitter contact in the mentioned order.

### CROSS-REFERENCE TO RELATED APPLICATION:

This application claims priority from German Patent Application No. 102006011240.7, which was filed on Mar. 10, 2006 and is incorporated herein by reference in its entirety.

### TECHNICAL FIELD

The present invention relates to a bipolar transistor and a method for using a bipolar transistor that is, for example, suitable for high frequency domains.

### BACKGROUND

Bipolar transistors (also referred to as transistors below), such as Si/SiGe hetero bipolar transistors, are conquering higher and higher frequency domains. Thereby, the transistors are entering frequency domains that have so far been the domain of III/V semiconductors. The performance of a transistor is decisively influenced by the design of the emitter. In bipolar transistors, a differentiation is made between polycrystalline and monocrystalline emitters.

FIG. 4 shows a bipolar transistor with a polycrystalline emitter. The transistor has a collector 10, a base 20, an emitter 30 and an emitter contact 40. The base 20 is implemented as monocrystalline base, and the emitter 30 as polycrystalline emitter. Thus, a current flow occurs between base 20 and emitter contact 40 through the polycrystalline emitter 30. The transistor is surrounded by insulating layers 60, 61, 62. A base contact layer 65 contacts the base. For generating the polycrystalline emitter 30, an oxide layer of the size of a monolayer is deposited on the monocrystalline base 20, and the same is coated with polysilicon, which then forms the emitter 30 and is doped. In a subsequent emitter drive-in, the dopant is activated and driven into the underlying monocrystalline silicon, so that an emitter base pn junction 50 is generated. At the same time, dopant profiles are smeared by diffusion. This is expressed in a reduced high-frequency performance. In the polycrystalline emitter, the strength of the oxide intermediate layer has a decisive influence on the current amplification. This requires an extremely good control of this layer during production to ensure reproducible results.

FIG. 5 shows a bipolar transistor having a monocrystalline emitter, which has, in correspondence to the transistor shown in FIG. 4, a collector 10, a base 20, an emitter 30 as well as an emitter terminal 40, wherein the emitter 30 is implemented as a monocrystalline emitter. In the monocrystalline emitter 30 the oxide intermediate layer is omitted on purpose so that the subsequent silicon deposition in the active area, i.e. the window in an insulating layer 60 otherwise covering the base, can be performed in a monocrystalline way. On the lateral dielectric layer 60, deposition is performed simultaneously, but in an amorphous manner. Doping can be performed in situ during deposition, so that the dopants are already electrically active and do not have to be activated, whereby steep dopant profiles are mostly maintained and the high-frequency performance is good. If the dopant is implanted afterwards, an activation temperature step with the disadvantages already mentioned above will have to be performed.

Compared to the polycrystalline emitter, the monocrystalline emitter requires only a low temperature budget. This results in less smearing doping profiles and thus in a better high-frequency performance. Thus, with Si/SiGe hetero bipolar transistors with monocrystalline emitters, a high-frequency performance can be obtained which allows the usage of such transistors as GSM power amplifiers in mobile phones. One characteristic of the monocrystalline emitter concept is a very low electric emitter resistance. Especially in power transistors, an emitter resistance that is too low is sometimes undesired because the same can cause instabilities of the transistor at high currents. The same are caused by current constrictions that can occur at small ratios of emitter-to-base resist. Since power transistors with monocrystalline emitters are rather inclined to be instable, mostly transistors with polycrystalline emitters are used. The same have a higher emitter resistance and are less inclined to be instable, as mentioned above. On the other hand, they also show a reduced high-frequency performance. This questions, for example, the usage in mobile phones, where high high-frequency performance is required. Besides that, the polycrystalline emitter has higher variations in current amplification during production. This causes an increased control effort and can lead to an increase of rejects.

U.S. Pat. No. 6,410,945 B1 and JP 10177595 describe bipolar transistors based on GaAs whose emitters have a layer-shaped structure. It is the object of this approach to reduce the emitter resistance.

### SUMMARY

According to an embodiment, a bipolar transistor may have a base and an emitter contact, wherein a monocrystalline layer and a polycrystalline layer are disposed between the base and the emitter contact in the mentioned order, and the monocrystalline layer has a surface facing away from the base and raised in relation to the base.

According to another embodiment, a method for producing a bipolar transistor may have the steps of providing a base, depositing a monocrystalline layer on the base, depositing a polycrystalline layer on the monocrystalline layer, and depositing an emitter contact on the polycrystalline layer.

Embodiments of the present invention are based on the knowledge that an emitter can be designed as a combination of a mono-emitter and a poly-emitter. Thereby, the advantages of both concepts can be combined and at the same time their disadvantages can be avoided. According to embodiments of the present invention, the emitter is divided into two layers. These are a monocrystalline lower layer, facing the base, and a polycrystalline upper layer. The lower layer corresponds to the monocrystalline emitter shown in FIG. 5 and has the advantage that the requirement of an oxide intermediate layer between base and emitter, as required in the polycrystalline emitter, can be avoided. Besides that, the monocrystalline layer provides a very good high-frequency performance. The upper layer of the inventive emitter corresponds to the polycrystalline emitter shown in FIG. 4. The polycrystalline emitter layer allows a series resistance adjustable by the production conditions. Thereby, the instabilities can be avoided that occur when the emitter is exclusively constructed of a monocrystalline layer and is used as a power transistor. A specific advantage of this layer structure is also that the nature of the polycrystalline cover layer has hardly any influence on the current amplification of the transistor and can thus be freely adjusted according to other boundary conditions.

The different layers of the inventive emitter can differ in structure, composition, doping and electric resistance and can be separated by boundary layers. Thereby, both the monocrystalline layer and the polycrystalline layer can be divided into further partial layers. A resistance of the layers can be set to a desired value by the selected production method, the selected thickness or the doping of the layers. Particularly, the resistance can be varied heavily by using the polycrystalline layer and can thus be adapted to required usage conditions. Thereby, resistance changes of the factor 10 are easily possible. Despite such resistor changes, the current amplification changes only slightly, since the same is defined by the emitter-base interface and reacts in a sensitive way to the changes of this interface. Thus, transistors with high emitter resistance, which still have a high current amplification, can be realized. The high emitter resistance has the advantage that instability of the transistor only occurs with higher currents and the transistor is thus also suitable for power applications.

### BRIEF DESCRIPTION OF THE DRAWINGS

Advantageous embodiments of the present invention will be detailed subsequently referring to the appended drawings, in which

FIG. 1 is a cross-sectional illustration of a bipolar transistor according to an embodiment of the present invention;

FIG. 2 is a cross-sectional representation of a bipolar transistor according to a further embodiment of the present invention;

FIG. 3 is a schematical illustration of a layer structure of a bipolar transistor according to an embodiment of the present invention;

FIG. 4 is a bipolar transistor having a known polycrystalline emitter; and

FIG. 5 is a bipolar transistor having a known monocrystalline emitter.

### DETAILED DESCRIPTION

In the following description of the advantageous embodiments, the same or similar reference numbers are used for the elements illustrated in the different drawings that have a similar effect, wherein a repeated description of these elements is omitted.

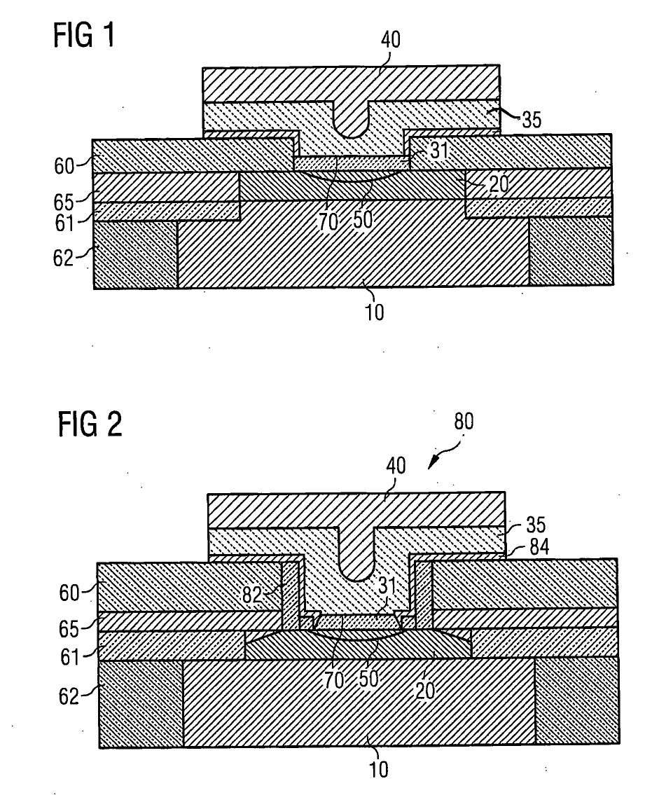

FIG. 1 shows a cross-sectional illustration through a bipolar transistor according to an embodiment. The transistor has a collector 10, a base 20, an emitter consisting of a monocrystalline layer 31 and a polycrystalline layer 35 as well as an emitter contact 40. A boundary layer 70 can be disposed between the monocrystalline emitter layer 31 and the polycrystalline emitter layer 35. A base contact layer 65 adjacent to the base can consist of polycrystalline material. The emitter contact 40 can consist of a silicide or a metal, such as tungsten. The substrate layers or insulating layers 60, 61, 62 surrounding the transistor can consist of a dielectric.

The transistor can be an npn transistor having an n⁻ collector, a p base and an n⁺ emitter. Alternatively, the reverse case would also be possible.

The structure of the collector 10 and the base 20 can be made up of known bipolar transistors. According to the embodiment, the base 20 is a monocrystalline base. The lower emitter layer 31 is also a monocrystalline layer. No oxide layer or the like is provided between the base 30 and the lower emitter layer 31. Rather, the two layers 20 and 31 are immediately adjacent to each other. An oxide layer 70, which serves for interrupting the grid information from layer 31 to layer 35, can be disposed between the monocrystalline emitter layer 31 and the polycrystalline emitter layer 35.

The polycrystalline emitter layer 35 is implemented such that the same forms a continuous separation layer between the monocrystalline emitter layer 31 and the emitter contact 40. Thus, no contact areas exist between the monocrystalline emitter layer 31 and the emitter contact 40 which would allow a direct current flow from the monocrystalline emitter layer 31 into the emitter contact 40. A current flow between base 20 and emitter contact 40 thus requires both a passage through the monocrystalline layer 31 and through the polycrystalline layer 35, wherein the resistances of both layers are added.

According to the embodiment shown in FIG. 1, the individual components of the transistor are shown as individual layers. The layers can be, for example, layers of a semiconductor device. The base layer is disposed on an upper (in relation to the figures) interface of the collector 10. The monocrystalline emitter layer 31 is disposed or deposited, respectively, on the surface of the base 20 opposite to the collector, so that the same has a surface facing away from the base, raised in relation to the base and projecting from the same, which extends within the active area, i.e. the opening in the insulation layer 60, up to a height that is further away from the base than the side of the insulation layer 60 facing the base. According to this embodiment, the monocrystalline layer 31 or the active area, respectively, is approximately disposed in the middle of the base 20. The polycrystalline layer 35 is disposed on the surface of the monocrystalline layer 31 opposite to the base 20. According to this embodiment, the polycrystalline layer 35 covers the whole surface of the monocrystalline layer 31. At the edge areas of the monocrystalline layer 31, a further dielectric layer can be disposed, which separates the layer from bordering substrate areas.

The polycrystalline layer 35 can be provided with a depression-shaped recess, which is approximately above the middle of the monocrystalline layer 31 or laterally in the middle of the active area, respectively. The emitter contact 40 allows contacting the transistor and is adjacent to the polycrystalline layer 35. Advantageously, the same consists of metal. According to the embodiment shown in FIG. 1, the emitter contact covers the whole surface of the polycrystalline layer 35 opposite to the monocrystalline layer 31.

FIG. 2 shows a cross-sectional illustration of a self-adjusting double-poly bipolar transistor according to a further embodiment. Here, the bipolar transistor shown in FIG. 2 can, for example, be particularly implemented as a double-poly-Si hetero bipolar transistor with a selectively grown SiGe base, as becomes easily clear from the embodiment of FIG. 2. In deviation from known bipolar transistors, the emitter is integrated as a mono-poly emitter with the layers 31, 35.

According to this embodiment, the polycrystalline layer 35 consists of n⁺ poly-Si and the base contact layer 65 of p⁺ poly-Si. According to this embodiment, both the monocrystalline base 20 and the monocrystalline emitter layer 31 are chamfered at the lateral faces.

A method for producing the transistor shown in FIG. 2 and particularly for integrating the inventive mono-poly emitter on the collector base structure will be described below.

The collector 10 as well as the base 20 can be produced according to known production methods. For example, first the insulating layer 61, the polycrystalline layer 65 and the insulation layer 60 are deposited on the whole area, and then an opening is etched into the layers 60 and 65 and the underlying insulation layer 61 is etched at the exposed surface through the formed opening, such that under-etching of the polycrystalline layer 65 results. Then, by selective growing, the base or the base layer structure 20, respectively, is grown on the exposed surface of the collector 10, which causes a skewed boundary between the polycrystalline layer 65 serving as base terminal and the monocrystalline base 20 as seen in FIG. 2. After finishing the base-collector structure comprising the insulating layers 60, 61, 62 as well as the base contact layer 65 apart from the collector 10 and base 20, an emitter window 80 is opened via, for example, lithography and anisotropic etching in an insulation material serving as a spacer and previously additionally deposited in the opening, so that the base 20 is exposed. Subsequent to a wet-chemical etching step, for example with diluted hydrofluoric acid, for removing the native oxide, the monocrystalline emitter layer 31 is deposited by differential growth, so that during the growth amorphous or polycrystalline silicon 84 is deposited simultaneously on the dielectric layers 60 and 82 of the environment. Thereby, it is advantageous to dope the monocrystalline layer 31 during epitaxy in situ by adding dopant gases. PH3, AsH3, and B2H6 can, for example, be used as doping gases.

The boundary layer 70 can be disposed between the monocrystalline layer 31 and the polycrystalline layer 35. A thin layer of silicon oxide is, for example, suitable as a boundary layer 70. In this case, the boundary layer 70 is generated after depositing the monocrystalline layer 31. The boundary layer hides the grid information of the underlying monocrystalline layer 31 and thus allows a transition to the polycrystalline growth of the polycrystalline layer 35. For obtaining polycrystalline growth, a certain minimum thickness is advantageous. A further increase of the thickness increases only the electric resistance of the boundary layer 70. The boundary layer 70 represents also a series resistance, which can be varied by the layer thickness of the boundary layer 70. A thin layer of silicon oxide is, for example, suitable as boundary layer 70. The thickness of the boundary layer 70 can, for example, be adjusted by wet-chemical treatment, oxygen plasma or ozone treatment and exposing to air, wherein the obtained thickness also depends on the doping of the monocrystalline base 31.

Other boundary layers 70 are possible, such as boundary layers 70 of silicon nitride or silicon carbide, wherein the same considerations apply for their adaptation.

After depositing the monocrystalline layer 31 or after depositing the additional boundary layer 70, respectively, the polycrystalline layer 35 is deposited under similar conditions as already described above with regard to the monocrystalline layer 31. It is favorable to first grow a thin seed layer (not shown in FIG. 2), which supplies the desired grain size distribution. Then, depositing the residual polycrystalline layer 35 can be performed under conditions optimized for a high throughput. In order to vary the resistance of the polycrystalline layer 35, doping can be adjusted in situ during the growth by changing the dopant gas flows.

According to this embodiment, the inventive emitter consists of four sub-layers. These are, from bottom to top, mono-Si as monocrystalline layer 31, an oxide layer as boundary layer 70, a poly-Si seed layer as well as a poly-Si cover as the polycrystalline layer 35. In the finished device, however, only three layers 31, 70, 35 are visible. The seed layer and cover layer cannot be differentiated, since both are polycrystalline and have the same doping and grain structure.

Growth of the mono- and polycrystalline layers 31, 35 can be accomplished in an epitaxy assembly with gas phase deposition, which is performed under the following conditions: temperature 500-700° C.; pressure 1-700 torr; carrier gas H2, N2 or Ar; silicon-providing gas SiH4, Si2H6 or Si3H8; doping gas B2H6, PH3 or AsH3. Optimizing for the respective layer is possible and appropriate within the mentioned parameter range for pressure and temperature.

The resistances of the individual emitter layers and of the whole emitter have a significant influence on the high-frequency behavior of the transistor as well as the suitability of the transistor as the power transistor.

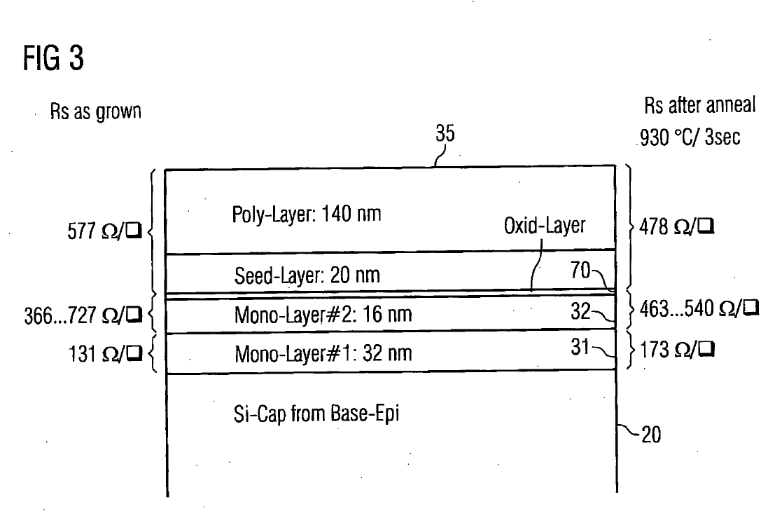

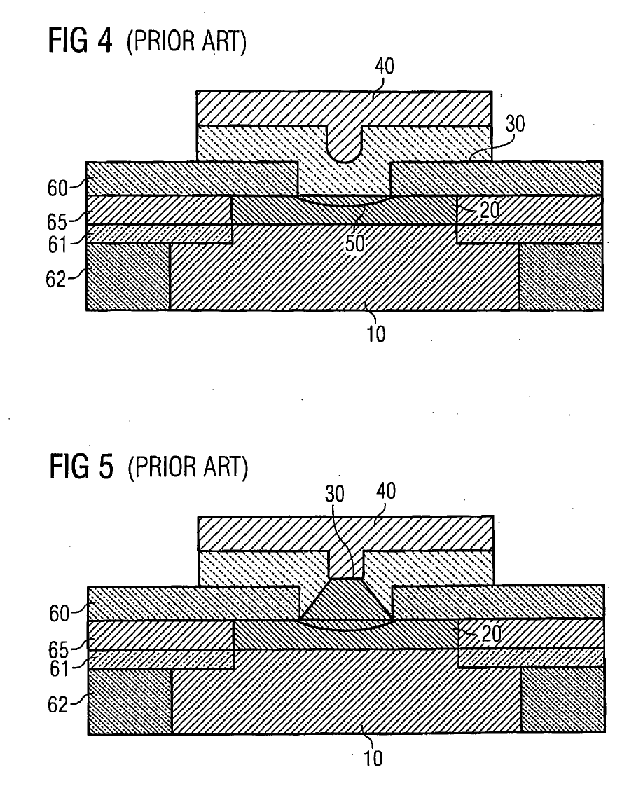

Based on FIG. 3, a possible layer structure of an emitter with associated resistances is described within an SiGe hetero bipolar transistor. The schematical illustration of a layer structure of an inventive emitter shown in FIG. 3 is based on a base 20 having a layer structure ending at the top or towards the emitter, respectively, with an Si cover. Sub-layers of the basis 20 lying further below, which are not shown in FIG. 3, comprise epitaxially grown layers of different mixtures of Si and Ge, wherein the proportion of Ge, for example, decreases towards the emitter and the SiGe layer is sufficiently thin in order to not lead to grid errors due to the different grid constants to the underlying Si layer. The collector also not shown in FIG. 3 can, for example, be formed in an Si substrate. Subsequently, two monocrystalline emitter layers 31, 32 are deposited on the Si cover 20. The first monocrystalline layer 31, referred to as monolayer #1, has a thickness of 32 nm. The second monocrystalline layer 32, referred to as monolayer #2, has a thickness of 16 nm. An oxide layer 70 is disposed on the second monocrystalline layer 32. A polycrystalline layer stack 35 consists of a seed layer with a thickness of 20 nm, which is disposed on the oxide layer 70, as well as of a subsequent polylayer with a thickness of 140 nm.

The first monocrystalline layer 31 is doped and has a layer resistance of 173Ω. This and the following resistances are no resistance in a vertical direction, which a current passes when flowing through the emitter, but a resistance in a horizontal direction. However, from this horizontal layer resistance, the vertical value, ultimately the characteristic of the transistor, can be concluded. Depending on the doping setting of the second monocrystalline layer 32 with a doping gas flow of 15, 40 or 100 sccm 1% AsH3, the layer resistance of the second monocrystalline layer 32 is between 463Ω and 540Ω. The resistance of the polycrystalline layer 35 is 478Ω. The measurement of the resistance has been performed for three seconds after a short heating to 900° C. Thereby, a value between 100Ω and 130Ω results as the overall layer resistance of the emitter. Layer resistances prior to heating can be taken from the left side of FIG. 3. Depositing the monocrystalline layers 31 and 32 by epitaxial growth can be performed with or without using a dopant gas dose for in-situ doping.

All mentioned values are merely exemplary and can be adapted for adapting the transistor to required conditions.

With regard to the monocrystalline layer, layer thicknesses between 5 nm and 100 nm are possible. The monocrystalline layer can consist of a single monocrystalline layer with a thickness of 25 nm, or a layer structure of two overlying monocrystalline layers with a thickness of 25 nm and 12 nm. The monocrystalline layer adjacent to the base can be thicker than the other of the two monocrystalline layers. Exemplary, a thickness ratio of 1:2 or smaller is given, so that the layer adjacent to the base is twice as thick as the layer above. As doping of the upper monocrystalline layer, i.e. the layer opposite to the polycrystalline layer, a doping setting with a gas flow of 5-200 sccm 1% AsH3 or 1% SiH3CH3 is possible. Exemplarily, values of 15, 30, 40, 100 or 150 sccm are mentioned.

An oxide layer between monocrystalline layer and polycrystalline layer can, for example, have a thickness between 0.1 nm and 1.5 nm. A lower thickness of the oxide layer is given by the functionality of hiding the grid structure of the underlying monocrystalline layer. The thickness of the oxide layer is limited by the intended resistance of this layer. The thicker the oxide layer, the higher the resistance. By appropriately selecting the thickness of the oxide layer, the overall resistance of the emitter can be adjusted.

Silane can be used, for example as the seed layer, and disilane as the polylayer. An overall thickness of the polycrystalline layer can have values between 50-300 nm. Exemplary, values of 103.4 nm, 157.8 nm and 160 nm are mentioned.

A specific resistance of the emitter can assume, for example, values of between 0.1 and 15 mΩ·cm. Exemplary, values of 0.43, 0.55, 6.64 and 7.55 mΩ·cm are mentioned.

A collector resistance in the finished transistor can assume, for example, values between 1 and 50Ω. Values of 2.77, 5.27, 7.75 and 23.7Ω are mentioned as examples.

All mentioned values as well as production parameters are selected exemplary and can be extended across the mentioned ranges both towards the top and the bottom to adjust the inventive transistor to altered conditions of usage. Particularly, the monocrystalline sheet can have more than two layers.

In the above embodiments, seen from bottom to top, a monocrystalline layer came first and then polycrystalline or amorphous layers, for example the oxide border layer. However, a polycrystalline layer can also come first and then another polycrystalline or amorphous layer. However, a transition from polycrystalline or amorphous layers to monocrystalline layers is problematic, since the grid information buried at the beginning is no longer available.

Further, the base material of the monocrystalline and the polycrystalline part of the emitter is not necessarily the same, such as Si in the previous embodiments. Rather, it is possible to implement the polycrystalline layer or layers, respectively, also in poly-Ge or poly-SiGe, while the monocrystalline layer is implemented in Si. In the case of several polyemitter layers, such as in FIG. 3, the same can also be formed of different polymaterials. The selection of the material has an influence on the resistance of the transistor, so that by allowing different materials the design freedom is increased. Of course, vice versa, for the monocrystalline layer mono-Ge or mono-SiGe can be used instead of mono-Si. Particularly in the case of several monoemitter layers, such as the layers 31 and 32 in FIG. 3, the same can also be formed with different materials. Advantageously, in this case, the lower monolayer or the monolayer lying closer to the base, respectively, consists of mono-Si, while the upper layer or the layer lying further away, respectively, consists of mono-SiGe. The growth of mono- and polycrystalline layers of Ge and SiGe can thereby be performed in an epitaxy assembly with gas phase deposition, which, for example, takes place in the above-mentioned conditions by using, alternatively or additionally to the silicon-providing gas, germanium-providing gas GeH₄.

The dimensions of the above-mentioned layers can be appropriately adjusted depending on the desired specification of the transistor. For example, the monocrystalline layers can, together or individually, have a thickness between 5 and 200 nm, while the polycrystalline layer or layers, together or individually, can have a thickness between 20 and 500 nm. The boundary layer 70 can be adjusted to a thickness between 0.1 and 2 nm. For the seed layer, a thickness between 5 and 100 nm can be provided.

The described monocrystalline and polycrystalline layers have been described as partial layers of the emitter. However, the polycrystalline layer could also be continued as a conductive trace or a contact and thus be seen as part of the emitter contact. In this regard, the area of the conductive trace forming the polycrystalline emitter layer could be implemented such that a required resistance of the polycrystalline emitter layer is obtained. The required resistance can be obtained by the already described measures, for example by adjusting the thickness of the conductive trace in this range.

In deviation from the above embodiments, the present invention can, of course, also be used in GaAs bipolar transistors.

The horizontal (in relation to the figures) implementation of the individual layers can be arbitrarily chosen. For example, circular or square implementations are possible. However, any other forms that maintain the order of the arrangement of the layers are possible.

While this invention has been described in terms of several advantageous embodiments, there are alterations, permutations, and equivalents which fall within the scope of this invention. It should also be noted that there are many alternative ways of implementing the methods and compositions of the present invention. It is therefore intended that the following appended claims be interpreted as including all such alterations, permutations, and equivalents as fall within the true spirit and scope of the present invention.

What is claimed is

1. A bipolar transistor, comprising:
a base;
an emitter contact; and
a monocrystalline layer and a polycrystalline layer disposed between the base and the emitter contact in the mentioned order, wherein the monocrystalline layer includes a surface facing away from the base and raised in relation to the base.

2. The bipolar transistor according to claim 1, wherein the polycrystalline layer is disposed between the monocrystalline layer and the emitter contact such that no direct contact exists between the monocrystalline layer and the emitter contact.

3. The bipolar transistor according to claim 1, wherein the monocrystalline layer comprises monocrystalline silicon, SiGe or germanium.

4. The bipolar transistor according to claim 1, wherein the polycrystalline layer comprises polycrystalline silicon, SiGe or germanium.

5. The bipolar transistor according to claim 1, wherein the emitter contact includes metal.

6. The bipolar transistor according to claim 1, wherein a boundary layer is disposed between the monocrystalline layer and the polycrystalline layer for interrupting a monocrystalline grid of the monocrystalline layer.

7. The bipolar transistor according to claim 6, wherein the boundary layer is an oxide layer, a silicon nitride layer or a silicon carbide layer.

8. The bipolar transistor according to claim 1, wherein the polycrystalline layer is adjacent to a seed layer, the seed layer disposed between the polycrystalline layer and the monocrystalline layer.

9. The bipolar transistor according to claim 1, wherein a further monocrystalline layer is disposed between the polycrystalline layer and the base, wherein the monocrystalline layer and the further monocrystalline layer are comprised of different dopings and/or a different base materials.

10. The bipolar transistor according to claim 9, wherein the monocrystalline layer contacts the base and has the same or a larger thickness than the further monocrystalline layer.

11. A method for producing a bipolar transistor, the method comprising:
providing a base;
depositing a monocrystalline layer on the base;
depositing a polycrystalline layer on the monocrystalline layer; and
depositing an emitter contact on the polycrystalline layer.

12. The method according to claim 11, wherein the polycrystalline layer is deposited on the monocrystalline layer such that the monocrystalline layer is fully covered, and such that no contact exists between the emitter contact and the monocrystalline layer.

13. The method according to claim 11, wherein the deposition of a further monocrystalline layer on the monocrystalline layer is performed between the deposition of the monocrystalline layer and the deposition of the polycrystalline layer, wherein both the monocrystalline layer and the further monocrystalline layer are doped in situ in a different manner by using different doping gas flows.

14. The method according to claim 11, wherein, prior to depositing the polycrystalline layer, a boundary layer is deposited on the monocrystalline layer for interrupting the monocrystalline grid.

15. The method according to claim 14, wherein the boundary layer is deposited in the form of a silicon oxide layer, a silicon nitride layer or a silicon carbide layer on the monocrystalline layer.

16. The method according to claim 11, wherein the polycrystalline layer is deposited by differential epitaxy.

17. A bipolar transistor comprising:
a base;
an emitter contact;
a monocrystalline layer disposed between the base and the emitter contact; and
a polycrystalline layer disposed between the monocrystalline layer and the emitter contact.

18. The bipolar transistor according to claim 17 wherein the monocrystalline layer include a first surface in direct contact with the base and a second surface facing away from the base and raised in relation to the base.

19. The bipolar transistor according to claim 17 further comprising means for interrupting a monocrystalline grid of the monocrystalline layer disposed between the monocrystalline layer and the polycrystalline layer.

20. The bipolar transistor according to claim 17 wherein the monocrystalline layer is a first monocrystalline layer and wherein a second monocrystalline layer is disposed between the polycrystalline layer and the first monocrystalline layer, wherein the first monocrystalline layer comprises a different doping and/or a different base material than the second monocrystalline layer.
